(19) United States
(12) Patent Application Publication
(10) Pub. No.: US 2013/0143063 A1
(43) Pub. Date: Jun. 6, 2013

(54) DEVICE HOUSING AND METHOD FOR MAKING SAME

(71) Applicants: DA-HUA CAO, Shenzhen City (CN); XU LIU, Shenzhen City (CN)

(72) Inventors: DA-HUA CAO, Shenzhen City (CN); XU LIU, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/474,833

(22) Filed: May 18, 2012

(30) Foreign Application Priority Data
Dec. 2, 2011 (CN) 201110395121.7

(51) Int. Cl. B32B 15/04; C23C 14/35; B32B 1/02

(52) U.S. Cl. 428/623; 428/34.1; 428/34.6; 204/192.15; 204/192.13

(57) ABSTRACT

The device housing includes a substrate having a bonding layer, a hard layer, and a color layer formed thereon, and in that order. The bonding layer is made of metal. The hard layer substantially consists of elemental Cr and elemental C. The color layer substantially consists of elemental Cr, elemental O, and elemental N. The atomic ratio of the elemental Cr, elemental O, and elemental N within the color layer is about (0.8-1.0):(1.2-1.5):(0.3-0.5). The color layer provides a bright blue color for the device housing. A method for making the device housing is also described.

### BACKGROUND

1. Technical Field

The present disclosure generally relates to device housings and a method for manufacturing the device housings, particularly device housings having a bright blue and metallic appearance and a method for making the device housings.

2. Description of Related Art

Traditional methods for providing a bright blue and metallic appearance for device housings include forming a very thin optical film on the device housings. The optical film may present a blue color by optical interference. However, the optical film is often too thin to be sufficiently abrasion-resistant. Moreover, the blue color created by the optical film is unstable and may change depending upon the angle at which the housing is viewed.

Therefore, there is room for improvement within the art.

### BRIEF DESCRIPTION OF THE DRAWINGS

Many aspects of the disclosure can be better understood with reference to the following figures. The components in the figures are not necessarily drawn to scale, the emphasis instead being placed upon clearly illustrating the principles of the disclosure.

FIG. 1 is a cross-sectional view of an exemplary embodiment of the present device housing.

FIG. 2 is a schematic view of a magnetron sputtering machine for manufacturing the device housing of FIG. 1.

### DETAILED DESCRIPTION

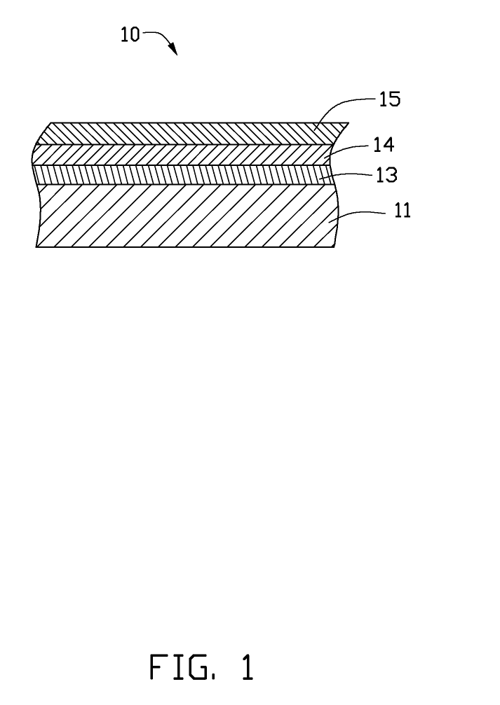

FIG. 1 shows an exemplary embodiment of a device housing 10. The device housing 10 includes a substrate 11, a bonding layer 13 directly formed on the substrate 11, a hard layer 14 directly formed on the bonding layer 13, and a color layer 15 directly formed on the hard layer 14. The device housing 10 may be a housing of mobile phone, personal digital apparatus, notebook computer, portable music player, GPS navigator, or digital camera. As used in this disclosure, “directly” means a surface of one layer is in contact with a surface of the other layer.

The substrate 11 may be made of metal, such as stainless steel, titanium alloy, or copper alloy. The substrate 11 may also be made of nonmetal materials, such as glass. In the exemplary embodiment, the substrate 11 is made of stainless steel.

The bonding layer 13 is made of a metal having a coefficient of thermal expansion approximately equal to the coefficient of thermal expansion of the substrate 11. For example, if the substrate 11 is made of stainless steel, the bonding layer 13 is preferably chromium. If the substrate 11 is made of titanium alloy, the bonding layer 13 is preferably titanium. The bonding layer 13 improves the attachment strength of the hard layer 14 and the color layer 15. The thickness of the bonding layer 13 may be about 0.05 μm to about 0.2 μm.

The hard layer 14 may substantially consist of elemental carbon (C) and elemental chromium (Cr). The atomic ratio of the elemental C and elemental Cr within the hard layer 14 may be about 1:1. The thickness of the hard layer 14 may be about 0.8 μm to about 2.0 μm. The hard layer 14 has a light color, such as silver, which does not effect the viewed color of the color layer 15. The hard layer 14 improves a total surface hardness of the device housing 10.

The color layer 15 may substantially consist of elemental Cr, elemental oxygen (O), and elemental nitrogen (N). The atomic ratio of the elemental Cr, elemental O, and elemental N within the color layer 15 may be about (0.8-1.0):(1.2-1.5):(0.3-0.5). The color layer 15 with according to this formula has a bright blue color when observed with the naked-eye. The color layer 15 has an L* value between about 35 to about 40, an a* value between about 0 to about 3, and an b* value between about −10 to about −15 in the CIE L*a*b* (CIE LAB) color space. The thickness of the color layer 15 may be about 0.3 μm to about 0.6 μm. The L* value can larger than 35 if the thickness of the color layer 15 is thinner than 0.3 μm, resulting in a light blue color of the color layer 15 (the larger the L* value is, the lighter the color is). The color layer 15 has a metallic appearance.

A method for manufacturing the device housing 10 may include: magnetron sputtering the bonding layer 13 on the substrate 11; magnetron sputtering the hard layer 14 on the bonding layer 13; and magnetron sputtering the color layer 15 on the hard layer 14.

Under sputtering conditions, magnetron sputtering the bonding layer 13 includes applying an electric power to a first target to sputter the first target material onto the substrate 11 and deposit the bonding layer 13. The first target is a metal which can be selected one from the group consisting of chromium, titanium, and zirconium. Under sputtering conditions, magnetron sputtering the hard layer 14 includes under sputtering conditions using acetylene as a reaction gas, applying an electric power to a second target to sputter the second target material onto the bonding layer 13 and deposit the hard layer 14. The second target is chromium. Under sputtering conditions, magnetron sputtering the color layer 15 includes under sputtering conditions using oxygen and nitrogen as reactions gases, applying an electric power to a third target to sputter the third target material onto the hard layer 14 and deposit the color layer 15. The third target is chromium.

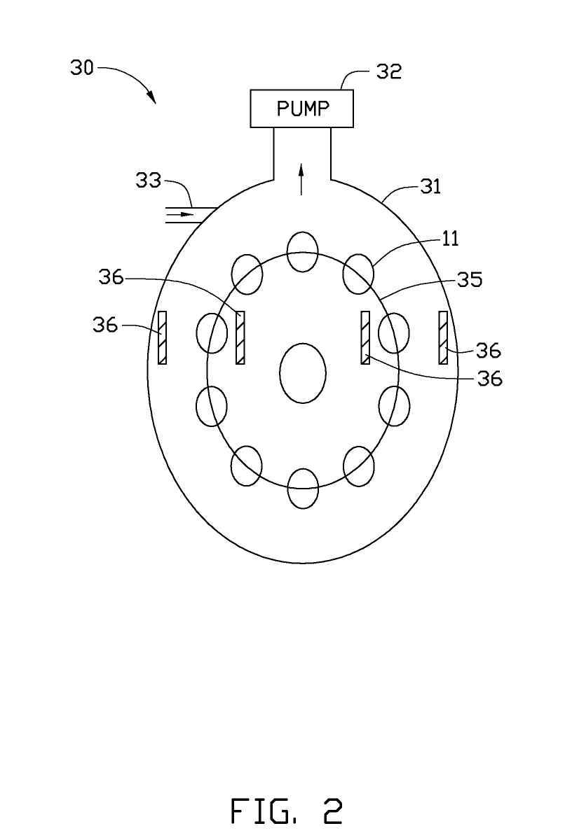

The bonding layer 13, hard layer 14, and color layer 15 can be formed in the same magnetron sputtering machine 30 as shown in FIG. 2. The machine 30 includes a vacuum chamber 31, a vacuum pump 32 connected to the chamber 31, and a plurality of gas inlets 33 communicating with the chamber 31. The vacuum pump 32 is used to evacuate the chamber 31. The machine 30 further includes a rotating bracket 35 and targets 36. The rotating bracket 35 rotates the substrate 11 in the chamber 31 relative to the targets 36. The targets 36 include the first, second, and the third target for the bonding layer 13, hard layer 14, and the color layer 15, respectively. Sputtering and reaction gases can be fed into the chamber 31 by the gas inlets 33.

The electric power may be provided by any power source for magnetron sputtering, such as intermediate frequency power source.

The magnetron sputtering conditions include: using an inert gas having a flow rate of about 150 Standard Cubic Centimeters per Minute (sccm) to about 250 sccm as a sputtering gas; maintaining an internal absolute pressure of the chamber 31 at about 0.3 Pa to about 0.6 Pa; maintaining an internal temperature of the chamber 31 at about 110° C. to about 180° C., wherein, the internal temperature of the chamber 31 during sputtering of the bonding layer 13 and the hard layer 14 may be about 150° C. to about 180° C., the internal temperature of the chamber 31 during sputtering of the color layer 15 may be about 110° C. to about 130° C.

The electric power for sputtering the bonding layer 13 may be about 10 kW to about 15 kW. Sputtering the bonding layer 13 may take about 5 minutes (min) to about 10 min. Under the above electric power and sputtering period, the bonding layer 13 may have a thickness of about 0.05 μm to about 0.2 μm.

The electric power for sputtering the hard layer 14 may be about 12 kW to about 16 kW. Sputtering the hard layer 14 may take about 60 min to about 90 min. The acetylene flow rate for sputtering the hard layer 14 may be about 60 sccm to about 90 sccm. Under the above electric power and sputtering period, the hard layer 14 may have a thickness of about 0.8 μm to about 2.0 μm.

The electric power for sputtering the color layer 15 may be about 12 kW to about 15 kW. The oxygen flow rate for sputtering the color layer 15 may be about 60 sccm to about 90 sccm. The nitrogen flow rate for sputtering the color layer 15 may be about 30 sccm to about 60 sccm. During the sputtering of the color layer 15, the thickness of the color layer 15 may be monitored by a film thickness monitor to stop the sputtering once the color layer 15 obtains a desired thickness.

Experiments show that the oxygen affects the brightness of the color layer 15. When the oxygen flow rate of the oxygen is greater than 90 sccm, the color layer 15 is still blue but too light and tends to be a little red. When the flow rate of the oxygen is less than 60 sccm, the color layer 15 is still blue but too dark and tends to be a little green.

To improve the adhesion of the layers 13, 14, and 15, a bias voltage may be applied to the substrate 11 during sputtering each of the layers 13, 14 and 15. The bias voltage applied on the substrate 11 may be about −100 volts (V) to about −150 V during sputtering the bonding layer 13. The bias voltage applied on the substrate 11 may be about −80 V to about −120 V during sputtering the hard layer 14. The bias voltage applied on the substrate 11 may be about −50 V.

To improve the bonding between the substrate 11 and the bonding layer 13, the substrate 11 may be cleaned by plasma cleaning before sputtering the bonding layer 13. The plasma cleaning is commonly known by one in the related art and is not described in detail.

Before the plasma cleaning, the substrate 11 may be cleaned in a solution (e.g., alcohol or acetone) in an ultrasonic cleaner to remove impurities and contaminations, such as grease, or dirt.

Specific examples of making the device housing 10 are described as following. The specific examples mainly emphasize the different process parameters of making the device housing 10. The sputtering of the bonding layer 13, hard layer 14, and color layer 15 are carried out in the same magnetron puttering machine 30.

### Example 1

A sample of 316L-type stainless steel substrate was cleaned with alcohol in an ultrasonic cleaner and then placed into the vacuum chamber 31 of the vacuum sputtering machine 30.

The vacuum chamber 31 was evacuated to maintain an internal pressure of about 6.0×10⁻³ Pa. Argon gas was fed into the vacuum chamber 31 to create an internal pressure of about 0.6 Pa. A bias voltage of about −800 V was applied to the substrate. Argon gas was ionized to plasma. The plasma struck against and cleaned the surface of the substrate. Plasma cleaning the substrate took about 15 min.

Then the argon flow rate was adjusted to be about 150 sccm to create an internal pressure of about 0.3 Pa. The internal temperature of the vacuum chamber 31 was maintained at about 150° C. A bias voltage of about −100 V was applied to the substrate. About 10 kW of power was applied to a chromium target, depositing a bonding layer of chromium on the substrate. The deposition of the bonding layer took about 10 min.

The power applied to the chromium target was adjusted to 12 kW. Acetylene as reaction gas having a flow rate of about 60 sccm was fed into the vacuum chamber 31. The bias voltage applied to the substrate was adjusted to −80 V, depositing a hard layer consisting of elemental Cr and elemental C onto the bonding layer, with other parameters the same as the deposition of the bonding layer. The deposition of the hard layer took about 80 min.

The internal temperature of the vacuum chamber 31 was adjusted to 110° C. The acetylene was switched off. Oxygen and nitrogen were simultaneously fed into the vacuum chamber 31 as reaction gases, with an oxygen flow rate of about 60 sccm and an nitrogen flow rate of about 30 sccm. The bias voltage applied to the substrate was adjusted to −50 V, depositing a color layer on the hard layer, with other parameters the same as the deposition of the hard layer. The thickness of the color layer was monitored by a film thickness monitor (provided by: Germany Inficon LTD.; type: XTC/3). The deposition was finished once the thickness of the color layer reached 0.6 μm. The color layer consisted of elemental Cr, elemental O, and elemental N.

The sample of example 1 was marked as S1. The S1 was bright blue under naked-eye observation. The color of the S1 was tested by a color difference meter. The results showed that the S1 has an L* value of about 35, an a* value of about 0, and an b* value of about −15 in the CIE L*a*b* (CIE LAB) color space.

### Example 2

A sample of 316L-type stainless steel substrate was cleaned with alcohol in an ultrasonic cleaner and then placed into the vacuum chamber 31 of the vacuum sputtering machine 30.

The vacuum chamber 31 was evacuated to maintain an internal pressure of about 4.0×10⁻³ Pa. Argon gas was fed into the vacuum chamber 31 to create an internal pressure of about 1.2 Pa. A bias voltage of about −1200 V was applied to the substrate. Argon gas was ionized to plasma. The plasma struck against and cleaned the surface of the substrate. Plasma cleaning the substrate took about 10 min.

Then the flow rate of the argon gas was adjusted to be about 250 sccm to create an internal pressure of about 0.6 Pa. The internal temperature of the vacuum chamber 31 was maintained at about 180° C. A bias voltage of about −150 V was applied to the substrate. About 15 kW of power was applied to a chromium target, depositing a bonding layer of chromium on the substrate. The deposition of the bonding layer took about 5 min.

The power applied to the chromium target was adjusted to 16 kW. Acetylene as reaction gas having a flow rate of about 90 sccm was fed into the vacuum chamber 31. The bias voltage applied to the substrate was adjusted to −120 V, depositing a hard layer consisting of elemental Cr and elemental C on the bonding layer, with other parameters the same as the deposition of the bonding layer. The deposition of the hard layer took about 70 min.

The internal temperature of the vacuum chamber 31 was adjusted to 130° C. The acetylene was switched off. Oxygen and nitrogen were simultaneously fed into the vacuum chamber 31 as reaction gases, with a oxygen flow rate of about 90 sccm and a nitrogen flow rate of about 60 sccm. The power applied to the chromium target was adjusted to 15 kW. The bias voltage applied to the substrate was adjusted to −50 V, depositing a color layer on the hard layer, with other parameters the same as the deposition of the hard layer. The thickness of the color layer was monitored by a film thickness monitor (provided by: Germany Inficon LTD.; type: XTC/3). The deposition was finished once the thickness of the color layer reached 0.3 μm. The color layer consisted of elemental Cr, elemental O, and elemental N.

The sample of example 2 was marked as S2. The S2 was a bright blue under naked-eye observation. The color of the S2 was tested by a color difference meter. The results showed that the S2 has an L* value of about 40, an a* value of about 3, and an b* value of about −10 in the CIE L*a*b* (CIE LAB) color space.

### Example 3

A sample of 316L type stainless steel substrate was cleaned with alcohol in an ultrasonic cleaner and then placed into the vacuum chamber 31 of the vacuum sputtering machine 30.

The vacuum chamber 31 was evacuated to maintain an internal pressure of about 6.0×10⁻³ Pa. Argon gas was fed into the vacuum chamber 31 to create an internal pressure of about 0.8 Pa. A bias voltage of about −1000 V was applied to the substrate. Argon gas was ionized to plasma. The plasma struck against and cleaned the surface of the substrate. Plasma cleaning the substrate took about 15 min.

Then the flow rate of the argon gas was adjusted to be about 160 sccm to create an internal pressure of about 0.4 Pa. The internal temperature of the vacuum chamber 31 was maintained at about 160° C. A bias voltage of about −150 V was applied to the substrate. About 12 kW of power was applied to a chromium target, depositing a bonding layer of chromium on the substrate. The deposition of the bonding layer took about 10 min.

The power applied to the chromium target was adjusted to 14 kW. Acetylene as reaction gas having a flow rate of about 70 sccm was fed into the vacuum chamber 31. The bias voltage applied to the substrate was adjusted to −100 V, depositing a hard layer consisting of elemental Cr and elemental C on the bonding layer, with other parameters the same as the deposition of the bonding layer. The deposition of the hard layer took about 80 min.

The internal temperature of the vacuum chamber 31 was adjusted to 120° C. The acetylene was switched off. Oxygen and nitrogen were simultaneously fed into the vacuum chamber 31 as reaction gases, with an oxygen flow rate of about 70 sccm and an nitrogen flow rate of about 40 sccm. The power applied to the chromium target was adjusted to 12 kW. The bias voltage applied to the substrate was adjusted to −50 V, depositing a color layer on the hard layer, with other parameters the same as the deposition of the hard layer. The thickness of the color layer was monitored by a film thickness monitor (provided by: Germany Inficon LTD.; type: XTC/3). The deposition was finished since the thickness of the color layer was 0.51 μm. The color layer consisted of elemental Cr, elemental O, and elemental N.

The sample of example 3 was marked as S3. The S3 was bright blue under naked-eye observation. The color of the S3 was tested by a color difference meter. The results showed that the S3 has an L* value of about 36.8, an a* value of about 1.3, and an b* value of about −12 in the CIE L*a*b* (CIE LAB) color space.

### Example 4

A sample of 316L type stainless steel substrate was cleaned with alcohol in an ultrasonic cleaner and then placed into the vacuum chamber 31 of the vacuum sputtering machine 30.

The vacuum chamber 31 was evacuated to maintain an internal pressure of about 5.0×10⁻³ Pa. Argon gas was fed into the vacuum chamber 31 to create an internal pressure of about 1.0 Pa. A bias voltage of about −1200 V was applied to the substrate. Argon gas was ionized to plasma. The plasma struck against and cleaned the surface of the substrate. Plasma cleaning the substrate took about 10 min.

Then the flow rate of the argon gas was adjusted to be about 220 sccm to create an internal pressure of about 0.5 Pa. The internal temperature of the vacuum chamber 31 was maintained at about 170° C. A bias voltage of about −100 V was applied to the substrate. About 15 kW of power was applied to a chromium target, depositing a bonding layer of chromium on the substrate. The deposition of the bonding layer took about 8 min.

The power applied to the chromium target was adjusted to 16 kW. Acetylene as reaction gas having a flow rate of about 80 sccm was fed into the vacuum chamber 31. The bias voltage applied to the substrate was adjusted to −120 V, depositing a hard layer consisting of elemental Cr and elemental C on the bonding layer, with other parameters the same as the deposition of the bonding layer. The deposition of the hard layer took about 70 min.

The internal temperature of the vacuum chamber 31 was adjusted to 125° C. The acetylene was switched off. Oxygen and nitrogen were simultaneously fed into the vacuum chamber 31 as reaction gases, with an oxygen flow rate of about 80 sccm and an nitrogen flow rate of about 50 sccm. The power applied to the chromium target was adjusted to 14 kW. The bias voltage applied to the substrate was adjusted to −50 V, depositing a color layer on the hard layer, with other parameters the same as the deposition of the hard layer. The thickness of the color layer was monitored by a film thickness monitor (provided by: Germany Inficon LTD.; type: XTC/3). The deposition was finished since the thickness of the color layer was 0.39 μm. The color layer consisted of elemental Cr, elemental O, and elemental N.

The sample of example 4 was marked as S4. The S4 was bright blue under naked-eye observation. The color of the S4 was tested by a color difference meter. The results show that the S4 has an L* value of about 38.7, an a* value of about 2.1, and an b* value of about −13.5 in the CIE L*a*b* (CIE LAB) color space.

### Results

The adhesive force of the layers coated on the samples S1-S4 was tested by a Crosshatch adhesion test. The vickers hardness of the surfaces of the samples S1-S4 was tested. The scratch resistance of the samples S1-S4 was tested by a scratch rod test. The results of the above tests are shown in the table 1.

TABLE 1

| Samples | Adhesive Force | Scratch Resistance | Wickers Hardness |
|---|---|---|---|
| S1 | Grade 0 | no exposure of the substrate | 586HV |
| | | under 20N | |
| S2 | Grade 0 | no exposure of the substrate | 548HV |
| | | under 20N | |
| S3 | Grade 0 | no exposure of the substrate | 578HV |
| | | under 20N | |
| S4 | Grade 0 | no exposure of the substrate | 540HV |
| | | under 20N | |

The color layer 15 has a bright blue color and a metallic appearance, providing the device housing 10 an attractive appearance. The bright blue color of the color layer 15 is the color of the material of color layer 15, which is more stable than a blue color produced with optical interference. Moreover, the hard layer 14 comprising elemental Cr and elemental C has a high hardness, providing the device housing 10 a good abrasion resistance.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A device housing, comprising:
a substrate;
a bonding layer formed on the substrate, the bonding layer made of metal;
a hard layer formed on the bonding layer, the hard layer substantially consisting of elemental Cr and elemental C; and
a color layer formed on the hard layer, the color layer substantially consisting of elemental Cr, elemental O, and elemental N, the atomic ratio of the elemental Cr, elemental O, and elemental N within the color layer being about (0.8-1.0):(1.2-1.5):(0.3-0.5).

2. The device housing as claimed in claim 1, wherein the color layer has an L* value between about 35 to about 40, an a* value between about 0 to about 3, and an b* value between about −10 to about −15 in the CIE LAB color space.

3. The device housing as claimed in claim 1, wherein the thickness of the color layer is about 0.3 μm to about 0.6 μm.

4. The device housing as claimed in claim 1, wherein the atomic ratio of the elemental C and elemental Cr within the hard layer is about 1:1.

5. The device housing as claimed in claim 1, wherein the substrate is made of metal.

6. The device housing as claimed in claim 5, wherein the substrate is made of a material selected from the group consisting of stainless steel, titanium alloy, and copper alloy.

7. The device housing as claimed in claim 5, wherein the bonding layer has a coefficient of thermal expansion approximate to the thermal expansion of the substrate.

8. The device housing as claimed in claim 1, wherein the substrate is made of glass.

9. A method for manufacturing a device housing, comprising:
magnetron sputtering a bonding layer on the substrate, the bonding layer made of metal;
magnetron sputtering a hard layer on the bonding layer, the hard layer substantially consisting of elemental Cr and elemental C; and
magnetron sputtering a color layer on the hard layer, the color layer substantially consisting of elemental Cr, elemental O, and elemental N, the atomic ratio of the elemental Cr, elemental O, and elemental N within the color layer being about (0.8-1.0):(1.2-1.5):(0.3-0.5).

10. The method of claim 9, wherein magnetron sputtering of the bonding layer uses an inert gas as a sputtering gas; applies a power of about 10 kW-15 kW to a metal target selected one from the group consisting of chromium, titanium, and zirconium; magnetron sputtering of the bonding layer is conducted at a temperature of about 150° C.-180° C. and takes about 5 min-10 min.

11. The method of claim 9, wherein magnetron sputtering of the hard layer uses an inert gas as a sputtering gas, uses acetylene having a flow rate of about 60 sccm-90 sccm as a reaction gas; applies a power of about 12 kW-16 kW to a chromium target; magnetron sputtering of the hard layer is conducted at a temperature of about 150° C.-180° C. and takes about 60 min-90 min.

12. The method of claim 9, wherein magnetron sputtering of the color layer uses an inert gas as a sputtering gas, uses oxygen having aflow rate of about 60 sccm-90 sccm and nitrogen having a flow rate of about 30 sccm-60 sccm as reaction gases; applies a power of about 12 kW-15 kW to a chromium target; magnetron sputtering of the color layer is conducted at a temperature of about 150° C.-180° C.

13. The method of claim 9, wherein magnetron sputtering of the bonding layer, hard layer, and the color layer is carried out in a vacuum chamber of a vacuum sputtering machine; the vacuum chamber maintains an internal absolute pressure of about 0.3 Pa to about 0.6 Pa during the magnetron sputtering of the bonding layer, hard layer, and the color layer.

14. The method of claim 9, wherein during the sputtering of the color layer, the thickness of the color layer is monitored by a film thickness monitor.
